(19) United States
(12) Patent Application Publication
(10) Pub. No.: US 2026/0215110 A1
(43) Pub. Date: Jul. 23, 2026

(54) DISPLAY APPARATUS AND METHOD OF MANUFACTURING THE SAME

(71) Applicant: LG Display Co., Ltd., Seoul (KR)

(72) Inventor: Jang Jo, Seoul (KR)

(21) Appl. No.: 19/372,181

(22) Filed: Oct. 28, 2025

(30) Foreign Application Priority Data
Jan. 23, 2025 (KR) 10-2025-0010265

(51) Int. Cl. H10K 59/131; H10K 59/12; H10K 59/124; H10K 59/80; H10K 59/88; H10K 71/00; H10K 71/60; H10K 102/00

(52) U.S. Cl. CPC H10K 59/131; H10K 59/1201; H10K 59/124; H10K 59/873; H10K 59/88; H10K 71/60; H10K 71/621; H10K 2102/351

(57) ABSTRACT

A substrate includes an active area and a non-active area, the non-active area including a pad area; a light-emitting element layer disposed on the active area; an encapsulation layer disposed to cover the light-emitting element layer; and one or more pad electrodes disposed on the pad area. A plurality of protrusions are formed on a surface of the pad electrode. A residual organic material is positioned on a portion of the pad area. Since a plurality of protrusions are formed on the surface of a pad electrode, surface adhesion of an organic layer that can be deposited on the surface of the pad electrode can be reduced, a pad open process can be easily performed to expose the surface of the pad electrode to the outside.

### CROSS REFERENCE TO RELATED APPLICATION

Pursuant to 35 U.S.C. § 119(a), this application claims the benefit of an earlier filing date and right of priority to Korean Patent Application No. 10-2025-0010265, filed on January 23, 2025, the contents of which is incorporated herein by reference in their entirety.

### TECHNICAL FIELD

The present specification relates to a display apparatus and a method of manufacturing a display apparatus.

### BACKGROUND

Display devices can be implemented in various forms, such as televisions, monitors, smartphones, tablet PCs, laptops, wearable devices, etc.

Among display devices that display various pieces of information as images, an organic light-emitting diode (OLED) display device is a self-luminous element that emits light by itself and has the advantages of a fast response time, high luminous efficiency and brightness, a large viewing angle, and excellent contrast ratio and color reproducibility.

Recently, as users’ demands for high-quality images have increased, development of high-resolution display devices is actively being conducted.

### SUMMARY

According to an implementation of the present specification, there is provided a display apparatus including a substrate including an active area, and a non-active area in which a pad area is disposed, a light-emitting element layer disposed on the active area, an encapsulation layer disposed to cover the light-emitting element layer, and one or more pad electrodes disposed on the pad area, wherein a plurality of protrusions are formed on a surface of the pad electrode, and a residual organic material is positioned on a portion of the pad area.

The pad electrode and the protrusion may be formed integrally as a single unit.

The pad electrode and the protrusion may be formed of different materials.

The protrusion may be formed by stacking one or more insulating layers.

The insulating layer may include an inorganic material.

The one or more insulating layers may be inserted into one or more holes formed in a portion of the surface of the pad electrode and protrude upward more than the surface of the pad electrode.

A recess may be formed between adjacent two of the plurality of protrusions, and the residual organic material may be positioned on the protrusion or the recess.

The recess and the plurality of protrusions may be disposed in a regular pattern.

The residual organic material may be randomly disposed in the pad area.

The residual organic material may be formed of the same material as the light-emitting element layer.

The light-emitting element layer may include a hole transport layer, an emissive material layer, and an electron transport layer, and the residual organic material may include the same material as one of the hole transport layer, the emissive material layer, and the electron transport layer.

The light-emitting element layer may include an extension extending in a direction in which the pad area is positioned, and the extension may include one or more of the hole transport layer, the emissive material layer, and the electron transport layer.

A vertical thickness of the extension may be smaller than a vertical thickness of the light-emitting element layer.

An end portion of the encapsulation layer may match an end portion of the extension.

The end portion of the extension may be spaced apart from the pad area.

According to an implementation of the present specification, there is provided a method of manufacturing a display apparatus, which includes providing a substrate including an active area, and a non-active area in which a pad area is disposed, forming a circuit part and a plurality of insulating layers on the substrate of the active area, forming one or more pad electrodes including a plurality of protrusions on a surface of the substrate of the pad area, forming a light-emitting element layer and a dummy light-emitting element layer on the substrate of the active area and the pad area, respectively, forming an encapsulation layer to cover the light-emitting element layer and the dummy light-emitting element layer, and removing the dummy light-emitting element layer and the encapsulation layer on the pad electrode.

The method may further include removing the dummy light-emitting element layer and the encapsulation layer using a tape peeling process.

After removing the dummy light-emitting element layer and the encapsulation layer, a residual organic material may be present on the pad electrode.

The light-emitting element layer may be formed to include a hole transport layer, an emissive material layer, and an electron transport layer, and the dummy light-emitting element layer and the residual organic material may include the same material as one of the hole transport layer, the emissive material layer, and the electron transport layer.

The protrusion may be formed by using a process of dry-etching or wet-etching the surface of the pad electrode.

The protrusion may be formed by stacking the plurality of insulating layers in the pad area.

The insulating layer may be formed of an inorganic material.

### BRIEF DESCRIPTION OF THE DRAWINGS

FIG. 1 shows a plurality of dies formed on a wafer.

FIG. 2 is a plan view of a display apparatus according to one implementation of the present specification.

FIG. 3 is a plan view of a display panel according to one implementation of the present specification.

FIG. 4 is a cross-sectional view along line I-I’ in FIG. 2.

FIG. 5 is a cross-sectional view along line II-II’ in FIG. 2.

FIG. 6 shows a cross-sectional view and a partially enlarged view of the display apparatus according to one implementation of the present disclosure before a pad open process is performed in a pad area.

FIG. 7 shows a cross-sectional view and a partially enlarged view of the display apparatus according to one implementation of the present disclosure after the pad open process is performed in the pad area.

FIGS. 8 and 9 are enlarged cross-sectional views of a protrusion of a pad electrode according to various implementations of the present specification.

FIG. 10 is an enlarged cross-sectional view of a protrusion of a pad electrode according to another implementation of the present specification.

### DETAILED DESCRIPTION OF THE INVENTION

Recently, head mounted display apparatuses including an organic light-emitting diode (OLED) display device have been developed. A head-mounted display apparatus is an apparatus that is worn on a user’s head to position a display screen in front of the user’s eyes. The head-mounted display apparatus can be used in various applications such as virtual reality (VR), augmented reality (AR), mixed reality (MR), etc. and can play an important role in providing users with an immersive experience.

The head-mounted display apparatus can be formed using OLED on silicon (OLEDoS) technology, which is a technology of forming an OLED on a silicon substrate. Generally, an OLEDoS can manufacture a display apparatus with higher resolution and higher density using a silicon wafer instead of a glass or plastic substrate.

Applying a microcavity structure to a head-mounted display apparatus with such an OLEDoS structure can help increase the efficiency of the display apparatus and improve color representation. The microcavity structure is a technology of amplifying light of a specific wavelength in an OLED display apparatus to increase color reproducibility. The microcavity structure can be composed of a thin dielectric layer and a reflective layer and can resonate and strengthen light of a specific wavelength to amplify the luminous efficiency in the OLED structure.

For example, VR has an advantage of providing excellent user immersion, allowing even a 1-inch image to appear as a 60-inch image. To this end, a small display apparatus with ultra-high resolution is applied to the head-mounted display apparatus.

Meanwhile, the display apparatus may include a pad area formed on a display panel, and a pad electrode in the pad area can be electrically connected to various driving integrated circuits using a method such as chip-on-film (COF) to receive various voltages and signals. During a process of forming the pad electrode on the display panel, some layers constituting the display panel can be formed on the entire front surface of a substrate to cover the pad electrode.

For example, a protective film covering the pad electrode can be formed on the pad electrode. In this case, the protective film can be an insulating layer formed of an inorganic material. Accordingly, since the protective film formed on the pad electrode interferes with the electrical connection between the pad electrode and an external circuit, a pad open process may be required to selectively remove the protective film covering the pad electrode and expose the pad electrode to the outside.

The pad open process can utilize a method of removing the protective layer by irradiating it with a laser. However, performing the pad open process with laser irradiation can lead to the following problems.

For example, the laser process uses a high-energy ultrashort-wave laser such as a picosecond laser, and during this process, the surface morphology of the pad electrode changes, causing damage, which can reduce the reliability of the pad electrode.

In addition, another problem that may arise is the generation of fine particles from the protective layer that is lifted off by the laser. In this case, when fine particles of the protective film are generated, they can be scattered to and re-deposited on other unintended areas of the display panel, causing contamination of the display panel. In addition, when the fine particles of the protective film, which is an insulating layer formed of an inorganic material, remain on the pad electrode, it can cause poor connection in the pad electrode.

In addition, since the laser process uses expensive picosecond laser equipment, an initial investment cost can be very high. In addition, since a maintenance cost is also quite high due to the characteristics of the precise laser equipment, it can lead to an increase in the overall manufacturing cost.

Accordingly, the present specification provides a display apparatus and a manufacturing method that allows for a pad open process that can simplify the process and increase reliability.

Implementations of the present specification are directed to providing a display apparatus and a method of manufacturing the same in which adhesion between a surface of a pad electrode and a surface of an organic layer can be reduced.

In addition, implementations of the present specification are directed to providing a display apparatus and a method of manufacturing the same in which an interface on a surface of a pad electrode can be stabilized.

In addition, implementations of the present specification are directed to providing a display apparatus and a method of manufacturing the same in which mechanical stress occurring during a bonding process of a pad electrode can be relieved.

In addition, implementations of the present specification are directed to providing a display apparatus and a method of manufacturing the same in which charge collection efficiency of a pad electrode can be increased.

In addition, implementations of the present specification are directed to providing a display apparatus and a method of manufacturing the same in which, during a pad open process, the process can be simplified, the occurrence of foreign substances can be reduced, and there is no need to change separate process condition settings according to the type of a protective film.

Objectives of implementations of the present specification are not limited to the above-described objects, and other objectives that are not mentioned will be able to be clearly understood by those skilled in the art from the following description.

According to the implementations of the present specification, since the plurality of protrusions are formed on the surface of the pad electrode, the surface adhesion of the organic layer that can be deposited on the surface of the pad electrode can be reduced. Accordingly, during the pad open process for removing the protective film formed to cover the pad electrode, the organic layer with reduced surface adhesion and the protective film can be removed at once after forming the organic layer on the surface of the pad electrode and depositing the protective film thereon, and thus the pad open process can be easily performed to expose the surface of the pad electrode to the outside.

In addition, according to the implementations of the present specification, since the residual organic material is positioned on a portion of the pad area in which the pad electrode is disposed, the interface on the surface of the pad electrode can be stabilized, thereby enhancing the reliability of the element.

In addition, according to the implementations of the present specification, since the residual organic material is positioned on a portion of the pad area in which the pad electrode is disposed, the residual organic material can serve as a kind of buffer during chip-on-film bonding, thereby relieving mechanical stress occurring during the bonding process. Accordingly, it is possible to prevent damage to the pad electrode due to bonding pressure and improve bonding reliability.

In addition, according to the implementations of the present specification, since the residual organic material positioned on a portion of the pad area in which the pad electrode is disposed is formed of the same material as the light-emitting element layer, the residual organic material can have charge or hole transport characteristics, thereby increasing the charge collection efficiency of the pad electrode.

In addition, according to the implementations of the present specification, since the protrusion formed on the surface of the pad electrode is formed by stacking one or more insulating layers including an inorganic material having a very weak bonding strength with the organic material layer, the surface adhesion of the organic material layer that can be deposited on the surface of the pad electrode can be further reduced.

In addition, according to the implementations of the present specification, since the tape peeling process is used during the pad open process, the process can be simplified compared to when using other processes such as a laser process, thereby significantly reducing the manufacturing time and cost.

In addition, according to the implementations of the present specification, since the tape peeling process is used in the pad open process, the occurrence rate of defects in the display apparatus caused by foreign substances such as fine particles that can occur when using other processes such as a laser process can be reduced. Accordingly, it is possible to improve the quality and reliability of the display apparatus.

In addition, according to the implementations of the present specification, since the tape peeling process is used in the pad open process, the pad open process can be performed without setting separate process conditions or without the mask process according to various types of protective films to be removed. Accordingly, it is possible to significantly improve the flexibility of the process and optimize the process, thereby reducing production energy.

Specific effects together with the above-described effects are described together with a description of the following detailed matters for carrying out the disclosure.

Advantages and features of the present specification and methods for achieving them will become clear by referencing implementations described below in detail in conjunction with the accompanying drawings. However, the present specification is not limited to the implementations disclosed below but can be implemented in various different forms, these implementations are merely provided to make the disclosure of the present specification complete and fully inform those skilled in the art to which the present specification pertains of the scope of the present specification, and the present specification is only defined by the scope of the appended claims.

Since shapes, sizes, ratios, angles, numbers, etc. disclosed in the drawings for describing the implementations of the present specification are illustrative, the present specification is not limited to the shown items. The same reference number denotes the same components throughout the specification. In addition, in describing the present specification, when it is determined that the detailed description of a related known technology may unnecessarily obscure the gist of the present specification, the detailed description thereof will be omitted. When “comprises,” “has,” “consists of,” and the like described in the present specification are used, other parts may be added unless “only” is used. When a component is expressed in a singular form, it includes a case in which the component is provided as a plurality of components unless specifically stated otherwise.

In construing a component, the component is construed as including a margin of error even when there is no separate explicit description.

When a positional relationship is described, for example, when the positional relationship between two parts is described using “on,” “above,” “under,” “next to,” etc., one or more other parts may be positioned between the two parts unless “immediately” or “directly” is used.

When the temporal relationship is described, for example, when the temporal relationship is described using the term “after,” “subsequently,” “then,” “before,” or the like, it may include a non-consecutive case unless the term “immediately” or “directly” is used.

Although terms such as first and second are used to describe various components, these components are not limited by these terms. The terms are only used to distinguish one component from another. Accordingly, a first component described below may be a second component within the technical spirit of the present specification.

Features of various implementations of the present specification may be coupled or combined partially or entirely, various technological interworking and driving are made possible, and the implementations may be implemented independently of each other or implemented together in an associated relationship.

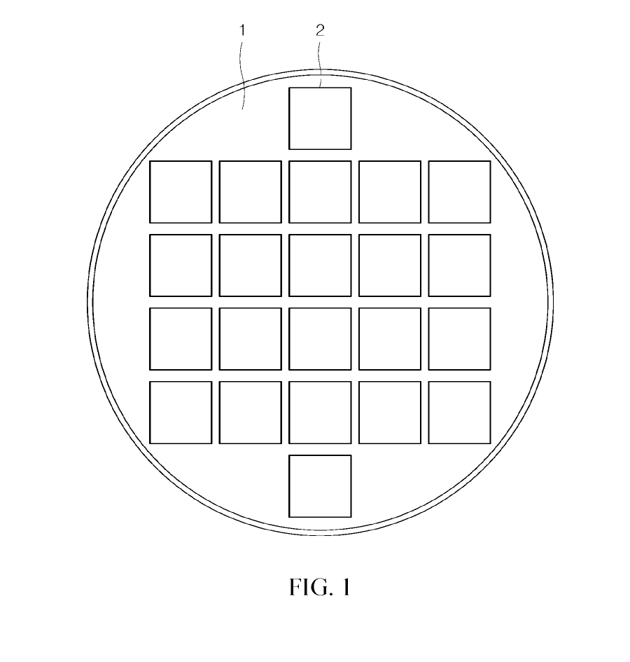

Hereinafter, a display panel and a display apparatus according to one implementation of the present specification will be described in detail with reference to FIGS. 1 to 3. An example in which a display apparatus to be described below is an organic light-emitting diode display apparatus will be described, but the present specification is not limited thereto.

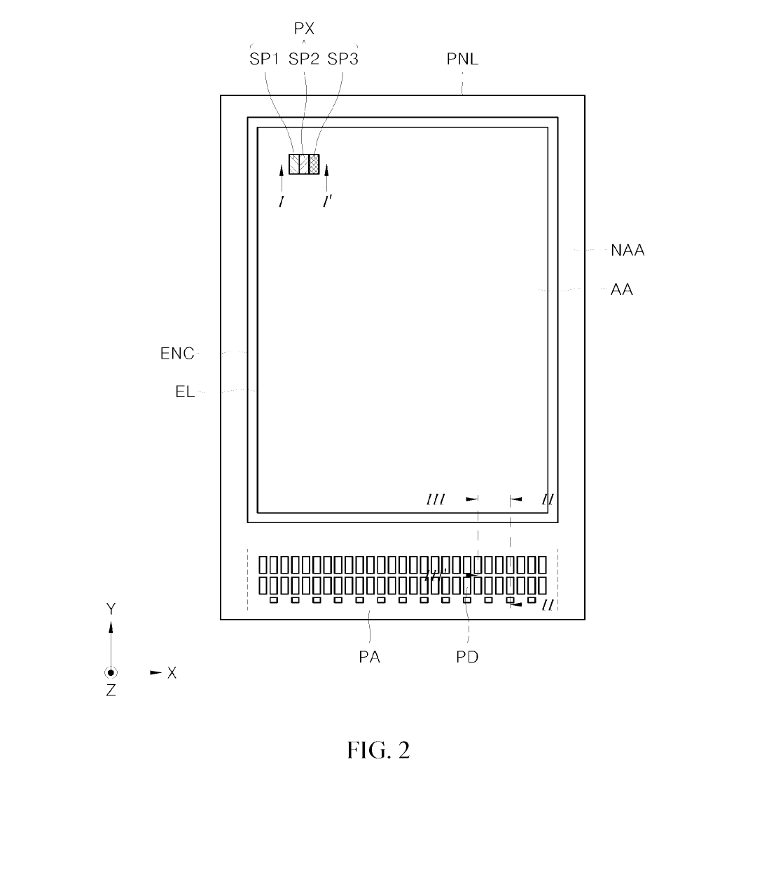

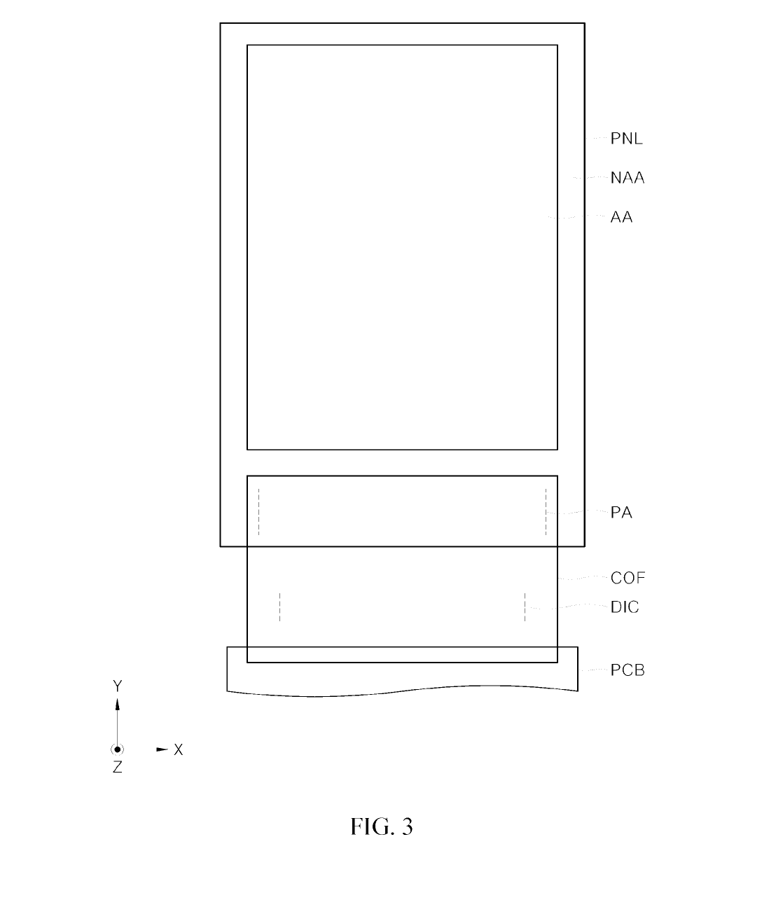

FIG. 1 is a schematic plan view showing a wafer 1 for manufacturing a display panel according to one implementation of the present invention and a plurality of dies 2 formed thereon. FIG. 2 is a plan view of a display panel before a chip-on-film (COF) bonding process is performed on a pad electrode, and FIG. 3 is a plan view of a display apparatus after the COF bonding process is performed on the pad electrode.

The wafer 1 has a thin, rounded plate shape formed of glass, plastic, silicon, etc., and the plurality of dies 2 may be arranged at regular intervals thereon. Each die 2 may form a display panel. Each display panel may be composed of a thin film circuit pattern including a thin film transistor (TFT), a pixel electrode, a signal line, a protective film, etc., and optical components such as a color filter, a light-emitting element layer, etc. These components may be sequentially formed on the wafer 1 through processes such as photolithography, deposition, etching, etc. Thereafter, the wafer 1 may be cut into individual dies 2 through a dicing process, and each die 2 may become a display apparatus through a subsequent process such as a COF bonding process for attaching a source driving integrated circuit.

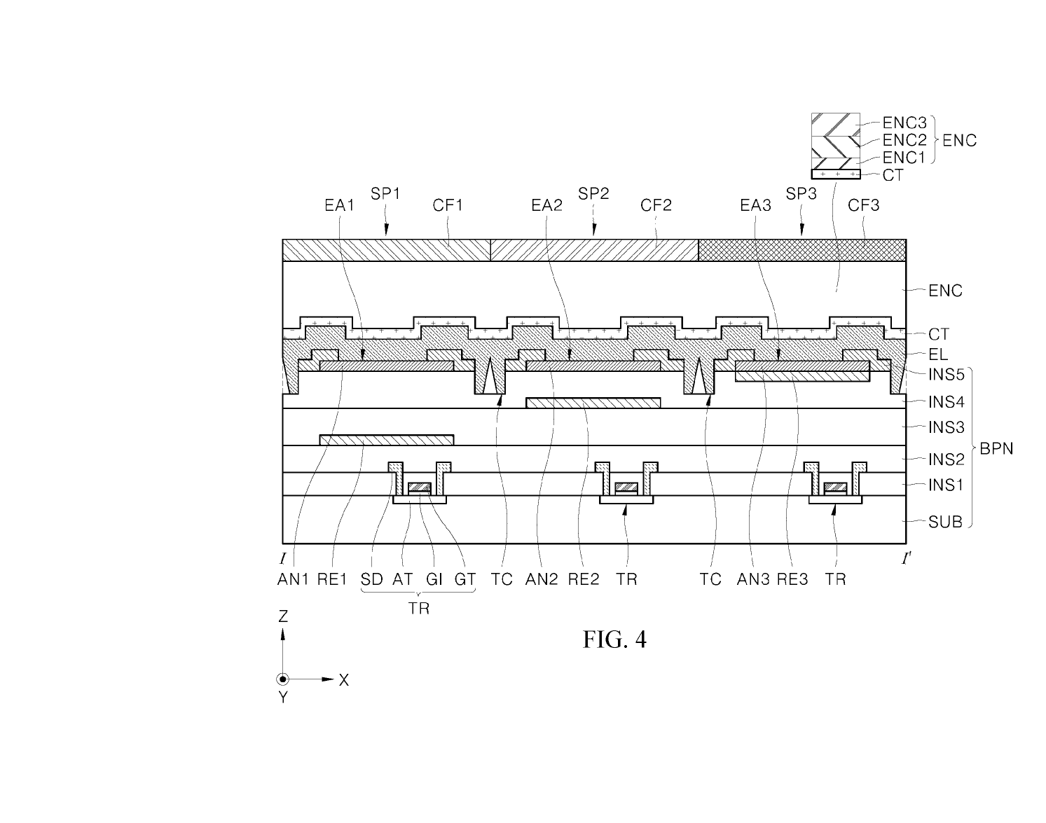

FIG. 2 shows a display panel before the COF bonding process is performed in a pad area, and FIG. 3 shows a display apparatus after the COF bonding process is performed in the pad area. FIG. 4 is a cross-sectional view of a plurality of sub-pixels of a display panel.

The display apparatus may include a display panel PNL, a chip-on-film COF connected to a pad area PA of the display panel PNL, and a printed circuit board PCB.

An active area AA on a substrate SUB may include a plurality of sub-pixels SP1, SP2, and SP3 each formed in one of areas defined by the intersection of a plurality of data lines extending in a first direction and a plurality of gate lines extending in a second direction intersecting the first direction. The first direction described in the present specification may be an X-axis direction, the second direction may be a Y-axis direction, and a Z-axis direction may be a direction perpendicular to the X-axis and the Y-axis. In addition, in the present specification, an implementation in which a pixel PX is composed of a first sub-pixel SP1, a second sub-pixel SP2, and a third sub-pixel SP3 will be described, but the present specification is not limited thereto, and the pixel PX may further include additional sub-pixels.

Each of the sub-pixels SP1, SP2, and SP3 may be implemented to emit light of the same color for each sub-pixel, such as white light, or implemented to emit light of a different color for each sub-pixel, such as red, green, or blue light. Hereinafter, an implementation in which the first sub-pixel SP1 implements red, the second sub-pixel SP2 implements green, and the third sub-pixel SP3 implements blue will be described. The plurality of sub-pixels SP1, SP2, and SP3 may be disposed in a form of a matrix arranged in a plurality of rows and columns.

A non-active area NAA may be disposed to surround the active area AA. The pad area PA on which a pad electrode PD for electrical connection with an external driving circuit is disposed may be positioned in the non-active area NAA positioned at one side of the active area AA. The chip-on-film COF, which is a flexible film, may be connected to the pad area PA through the chip-on-film COF bonding process. A driving chip DIC may be mounted on the chip-on-film COF. The printed circuit board PCB may be connected to the chip-on-film COF. A timing controller, a power supply unit, etc. may be mounted on the printed circuit board PCB. The printed circuit board PCB may be a flexible printed circuit board.

Referring to FIG. 4, the display panel PNL according to one implementation of the present specification may include a backplane substrate BPN, a light-emitting element layer EL, a cathode electrode CT, and an encapsulation layer ENC. The backplane substrate BPN may include a substrate SUB, a transistor TR, first to fifth insulating layers INS1, INS2, INS3, INS4, and INS5, first to third reflective electrodes RE1, RE2, and RE3, and first to third anode electrodes AN1, AN2, and AN3. The display panel according to one implementation of the present specification may be implemented in a so-called top emission method in which light emitted from the light-emitting layer is emitted through the cathode electrode.

The substrate SUB may be formed of glass or plastic such as polyimide, but is not limited thereto, and may also be formed of a semiconductor material such as a silicon wafer. On the substrate SUB, a driving circuit including various signal lines, transistors, capacitors, etc. may be disposed in each of the sub-pixels SP1, SP2, and SP3. The signal lines may include a gate line, a data line, a power line, and a reference line, and the transistors may include a switching transistor and a driving transistor TR. For example, the switching transistor and the driving transistor may be formed on the substrate SUB using a complementary metal oxide semiconductor (CMOS) process. In the implementations of the present specification, the driving transistor TR is shown for convenience of description.

The transistor TR may include an active layer AT formed on the substrate SUB, a gate insulating film GI sequentially stacked on the active layer AT, a gate electrode GT, and a pair of source/drain electrodes SD positioned at both sides of the gate electrode GT and connected to the active layer AT. The gate electrode GT and the source/drain electrode SD may be formed of a metal material and formed of a single layer or multiple layers formed of one selected from the group including chromium (Cr), aluminum (Al), silver (Ag), copper (Cu), magnesium (Mg), molybdenum (Mo), and titanium (Ti), or an alloy thereof.

A first insulating layer INS1 may be disposed on the substrate SUB. The first insulating layer INS1 may cover the gate electrode GT of the transistor TR and the like disposed on the substrate SUB. The source/drain electrodes SD of the transistor TR may be disposed on the first insulating layer INS1 and connected to the active layer AT of the transistor TR through contact holes passing through the first insulating layer INS1.

A second insulating layer INS2 may be disposed on the first insulating layer INS1 and may cover the source/drain electrodes SD of the transistors TR. A first reflective electrode RE1 may be disposed on the second insulating layer INS2. The first reflective electrode RE1 may be disposed on the first sub-pixel SP1. A third insulating layer INS3 may be disposed on the second insulating layer INS2, and the third insulating layer INS3 may cover the first reflective electrode RE1. The second reflective electrode RE2 may be disposed on the third insulating layer INS3. The second reflective electrode RE2 may be disposed in the second sub-pixel SP2. A fourth insulating layer INS4 may be disposed on the third insulating layer INS3, and the fourth insulating layer INS4 may cover the second reflective electrode RE2.

The first insulating layer INS1, the second insulating layer INS2, the third insulating layer INS3, and the fourth insulating layer INS4 may be formed of a single layer or multiple layers of an inorganic film such as silicon nitride, aluminum nitride, zirconium nitride, titanium nitride, hafnium nitride, tantalum nitride, silicon oxide, aluminum oxide, titanium oxide, etc. However, the present specification is not limited thereto, and one or more of the first insulating layer INS1, the second insulating layer INS2, the third insulating layer INS3, and the fourth insulating layer INS4 may be formed of a single layer or multiple layers of an organic film such as an acrylic resin, an epoxy resin, a phenolic resin, a polyamide resin, a polyimide resin, etc. For example, the fourth insulating layer INS4 may serve to planarize a step occurring due to a lower circuit element including the driving transistor TR. The fourth insulating layer INS4 may be referred to as a planarization layer.

The first anode electrode AN1, the second anode electrode AN2, the third reflective electrode RE3, the third anode electrode AN3 may be disposed on the fourth insulating layer INS4. The first anode electrode AN1 may be disposed in the first sub-pixel SP1, the second anode electrode AN2 may be disposed in the second sub-pixel SP2, and the third reflective electrode RE3 and the third anode electrode AN3 may be disposed in the third sub-pixel SP3.

The first reflective electrode RE1, the second reflective electrodes RE2, and the third reflective electrodes RE3 may be formed of a metal material having high reflectivity, such as silver (Ag), a silver alloy, aluminum (Al), or an aluminum alloy. The first to third anode electrodes AN1, AN2, and AN3 may include a transparent metal oxide, such as indium tin oxide (ITO) or indium zinc oxide (IZO). The anode electrode AN may be referred to as a pixel electrode.

The third reflective electrode RE3 and the third anode electrode AN3 may come into contact with each other in the third sub-pixel SP3. In one implementation, instead of the third reflective electrode RE3 and the third anode electrode AN3 coming into contact with each other, an additional insulating layer may be further disposed on the third reflective electrode RE3, and the first to third anode electrodes AN1, AN2, and AN3 may be disposed on the additional insulating layer.

Each of the first to third anode electrodes AN1, AN2, and AN3 may be electrically connected to the source/drain electrodes SD of the transistor TR disposed on the substrate SUB. The first anode electrode AN1 may be electrically connected to the first reflective electrode RE1, and the first reflective electrode RE1 may be electrically connected to the source/drain electrodes SD of the transistor TR. The second anode electrode AN2 may be electrically connected to the second reflective electrode RE2, and the second reflective electrode RE2 may be electrically connected to the source/drain electrodes SD of the transistor TR.

A fifth insulating layer INS5 may be disposed on the fourth insulating layer INS4. The fifth insulating layer INS5 may cover edge areas of the first to third anode electrodes AN1, AN2, and AN3. A portion of an upper surface of the first anode electrode AN1 may be a first light-emitting area EA1, a portion of an upper surface of the second anode electrode AN2 may be a second light-emitting area EA2, and a portion of an upper surface of the third anode electrode AN3 may be a third light-emitting area EA3, and the portions of the first to third anode electrodes are exposed without being covered by the fifth insulating layer INS5. The fifth insulating layer INS5 may be a bank or pixel definition film. The fifth insulating layer INS5 may include an organic insulating film such as polyimide, an epoxy, etc. In one example, the fifth insulating layer INS5 may include one of a black resin, graphite, or black ink. In addition, the fifth insulating layer INS5 may be formed of an inorganic insulation material. In one implementation, the fifth insulating layer INS5 may be formed of silicon nitride.

A concave trench TC may be formed in the fifth insulating layer INS5 and the fourth insulating layer INS4. The trench TC may pass through the fifth insulating layer IN5 in boundary areas between the sub-pixels SP1, SP2, and SP3 and extend to a predetermined area of the fourth insulating layer INS4. In one implementation, the trench TC may extend to the third insulating layer INS3 below the fourth insulating layer INS4. Each trench TC may have a gap formed therein, and the gap may disconnect at least a portion of the light-emitting element layer EL. Since at least a portion of the light-emitting element layer EL is disconnected by the gap formed in the trench TC, it is possible to prevent leakage current from occurring between adjacent sub-pixels SP1, SP2, and SP3 through the light-emitting element layer EL.

The light-emitting element layer EL may be disposed in common in the first to third sub-pixels SP1, SP2, and SP3. The light-emitting element layer EL may be disposed on the first to third anode electrodes AN1, AN2, and AN3 and the fifth insulating layer INS5.

The light-emitting element layer EL may be configured to emit, for example, white (W) light. In one example, the light-emitting element layer EL may include an organic material that emits white light. The light-emitting element layer EL may include a hole transport layer (HTL), an emissive material layer (EML), and an electron transport layer (ETL). In addition, the light-emitting element layer EL may further include a hole blocking layer (HBL), a hole injecting layer (HIL), an electron blocking layer (EBL), and an electron injecting layer (EIL).

The hole injecting layer (HIL) may serve to efficiently inject holes from the anode electrode AN into the emissive material layer (EML). The hole transport layer (HTL) may serve to help holes move to the emissive material layer (EML). The emissive material layer (EML) is a layer that substantially emits light and emits light by recombining holes and electrons. The electron transport layer (ETL) may serve to inject electrons and move the electrons to the emissive material layer (EML). The electron injecting layer (EIL) may serve to efficiently inject electrons from the cathode electrode CT into the emissive material layer (EML). The light-emitting element layer EL may have a tandem structure including a multi-stack structure in which at least two stacks including the above layers are stacked. For example, when two or more stacks are stacked, a charge generation layer CGL may be disposed between the plurality of stacks. The charge generation layer CGL may supply charges to each stack and control a charge balance between the stacks. The charge generation layer CGL between adjacent sub-pixels may be disconnected by the gap formed in the trench TC.

The cathode electrode CT may be disposed on the light-emitting element layer EL. The cathode electrode CT may be disposed in common in the first to third sub-pixels SP1, SP2, and SP3. The cathode electrode CT may be formed of a semi-transmissive conductive material. The cathode electrode CT may be formed of a metal material such as magnesium (Mg), silver (Ag), or an alloy of magnesium (Mg) and silver (Ag). The cathode electrode CT may be formed in the form of a thin film having a thickness of several nanometers to tens of nanometers. Accordingly, it is possible to obtain the microcavity effect in the first to third sub-pixels SP1, SP2, and SP3 as light is repeatedly reflected and re-reflected between the cathode electrode CT and the first to third reflective electrodes RE1, RE2, and RE3. The microcavity effect is a phenomenon in which an emission spectrum varies. For example, the emission spectrum may be changed by the interference effect of light caused by the reflectivity of the reflective electrode and the transmittance of the cathode electrode and by a distance between the reflective electrode and the cathode electrode. The microcavity effect may be used to selectively emit light of a specific wavelength.

According to one implementation of the present specification, since a first distance between the first reflective electrode RE1 and the cathode electrode CT in the first sub-pixel SP1, a second distance between the second reflective electrode RE2 and the cathode electrode CT in the second sub-pixel SP2, and a third distance between the third reflective electrode RE3 and the cathode electrode CT in the third sub-pixel SP3 may all be configured differently, it is possible to increase light extraction efficiency and color purity of light of different colors, for example, red, green, and blue light in the first to third sub-pixels SP1, SP2, and SP3 by the microcavity effect.

The encapsulation layer ENC may be disposed on the cathode electrode CT. The encapsulation layer ENC may be disposed on the light-emitting element layer EL to protect the light-emitting element layer EL from external moisture. The encapsulation layer ENC may include a plurality of encapsulation layers stacked on the cathode electrode CT. For example, the encapsulation layer ENC may include a first encapsulation layer ENC1, a second encapsulation layer ENC2, and a third encapsulation layer ENC3 that are sequentially stacked from the bottom to the top. The encapsulation layer ENC may be formed to cover the light-emitting element layer EL of the active area AA, and formed to extend to the non-active area NAA. In this case, the encapsulation layer ENC may be removed so as not to cover the pad area PA.

The encapsulation layer ENC may be formed by alternately stacking a plurality of inorganic layers and a plurality of organic layers. In addition, the encapsulation layer ENC may be formed by stacking a plurality of inorganic layers. For example, the inorganic layer may be formed of an inorganic material such as silicon nitride (SiNₓ), silicon oxide (SiOₓ), aluminum oxide (AlOₓ), etc., and the organic layer may use an epoxy-based polymer or an acryl-based polymer, but the present specification is not limited thereto. For example, the first encapsulation layer ENC1 may include aluminum oxide, the second encapsulation layer ENC2 may include silicon nitride, and the third encapsulation layer ENC3 may include silicon nitride. In addition, as another example, the first encapsulation layer ENC1 may include aluminum oxide, the second encapsulation layer ENC2 may include an epoxy-based polymer, and the third encapsulation layer ENC3 may include silicon nitride.

First to third color filters CF1, CF2, and CF3 may be disposed on the encapsulation layer ENC. The first color filter CF1 overlapping the first light-emitting area EA1 may be disposed in the first sub-pixel SP1 The second color filter CF2 overlapping the second light-emitting area EA2 may be disposed in the second sub-pixel SP2 The third color filter CF3 overlapping the third light-emitting area EA3 may be disposed in the third sub-pixel SP3 The first color filter CF1 may be a red color filter that transmits light of red, the second color filter CF2 may be a green color filter that transmits light of green, and the third color filter CF3 may be a blue color filter that transmits light of blue.

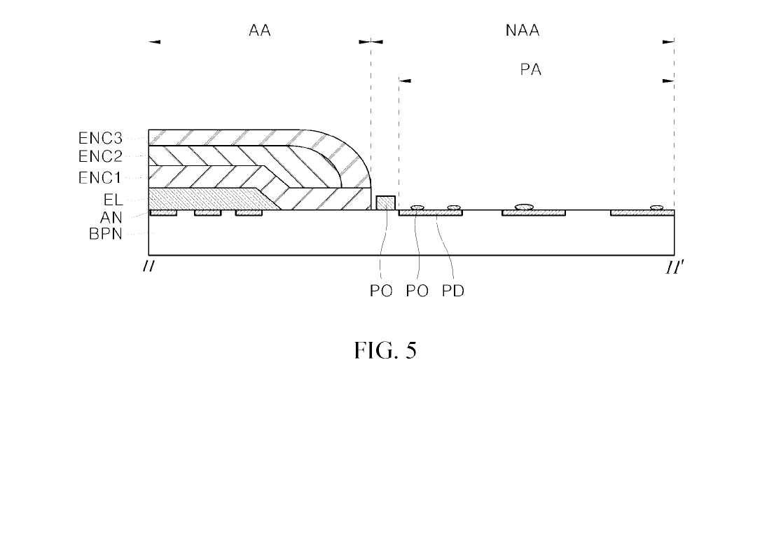

Hereinafter, the pad area PA according to one implementation of the present specification will be described in more detail with further reference to FIGS. 5 to 10.

Referring to FIG. 5, a plurality of anode electrodes AN may be disposed in the active area AA, and the light-emitting element layer EL may be disposed on the anode electrode AN. The first encapsulation layer ENC1, the second encapsulation layer ENC2, and the third encapsulation layer ENC3 may be sequentially stacked on the light-emitting element layer EL to cover the light-emitting element layer EL.

A plurality of pad electrodes PD may be disposed to be spaced a predetermined distance from each other in the pad area PA of the non-active area NAA. A residual organic material PO may be positioned on a portion of the pad area PA and a portion of the non-active area NAA.

For example, the portion of the residual organic material PO may be disposed on the pad electrode PD. In this case, the residual organic material PO may be disposed on a portion of an upper surface of the pad electrode PD. An area of an area in which the residual organic matter PO is not disposed on the pad electrode PD may be larger than an area of the area in which the residual organic material PO is disposed on the pad electrode PD. Since the upper surface of the pad electrode PD needs to be exposed to the outside and electrically connected to the chip-on-film COF, the residual organic material PO disposed on the pad electrode PD may be locally positioned on a portion of the pad electrode PD to the extent that it does not interfere with the electrical connection between the pad electrode PD and the chip-on-film COF. In addition, some residual organic materials PO may be disposed between adjacent pad electrodes PD and may also be disposed in the non-active area NAA between the pad area PA and the active area AA.

The residual organic material PO may be formed of the same material as the light-emitting element layer EL in the active area AA. In addition, the residual organic material PO may be disposed on the same layer as the light-emitting element layer EL. For example, the residual organic material PO may be organic particles remaining after a dummy light-emitting element layer DEL formed to cover the pad area PA is removed. That is, the residual organic material PO may be organic particles remaining after the light-emitting element layer EL is formed in the form of a continuous layer by the same deposition process as the light-emitting element layer and then an additional removal process is performed.

For example, the residual organic material PO may include a material constituting one or more layers constituting the light-emitting element layer EL. In one implementation, the residual organic material PO may include a material that is the same as one of the hole transport layer or the electron transport layer or include two materials constituting the hole transport layer and the electron transport layer. In another implementation, the residual organic material PO may include materials of one or more of the hole blocking layer, the hole injecting layer, the electron blocking layer, and the electron injecting layer.

Accordingly, according to the implementations of the present specification, since the residual organic material PO is positioned on the portion of the pad area PA in which the pad electrode PD is disposed, the residual organic material PO may serve as a kind of buffer during chip-on-film bonding, thereby relieving mechanical stress occurring during the bonding process. Accordingly, it is possible to prevent damage to the pad electrode due to bonding pressure and improve bonding reliability.

In addition, according to the implementations of the present specification, since the residual organic material PO positioned on the portion of the pad area PA in which the pad electrode PD is disposed is formed of the same material as the light-emitting element layer EL, the residual organic material PO may have charge or hole transport characteristics, thereby increasing the charge collection efficiency of the pad electrode PD.

In addition, according to the implementations of the present specification, since the residual organic material PO is positioned on the portion of the pad area PA in which the pad electrode PD is disposed, the interface on a surface of the pad electrode PD can be stabilized, thereby enhancing the reliability of the element.

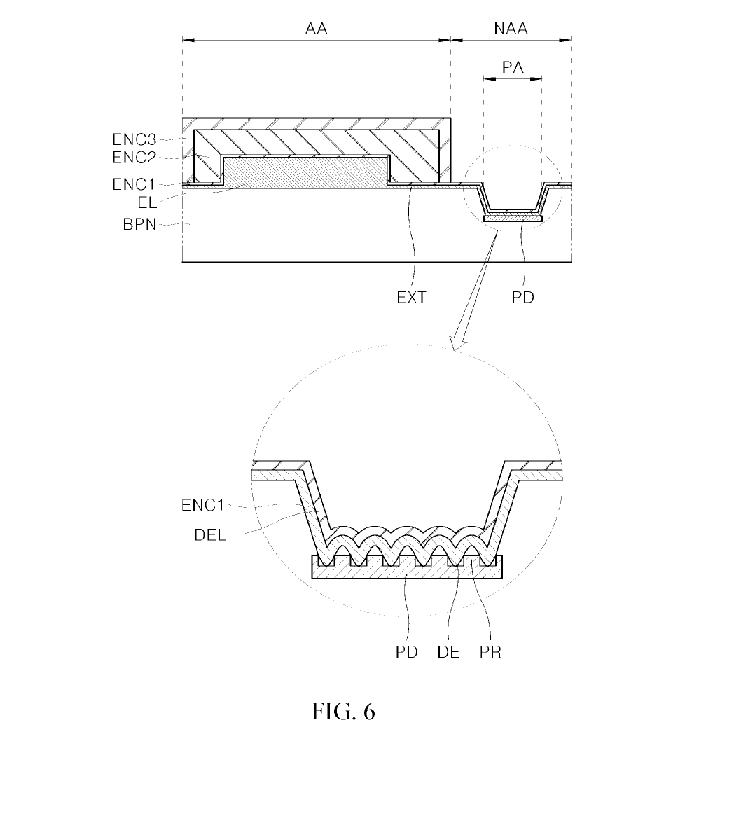

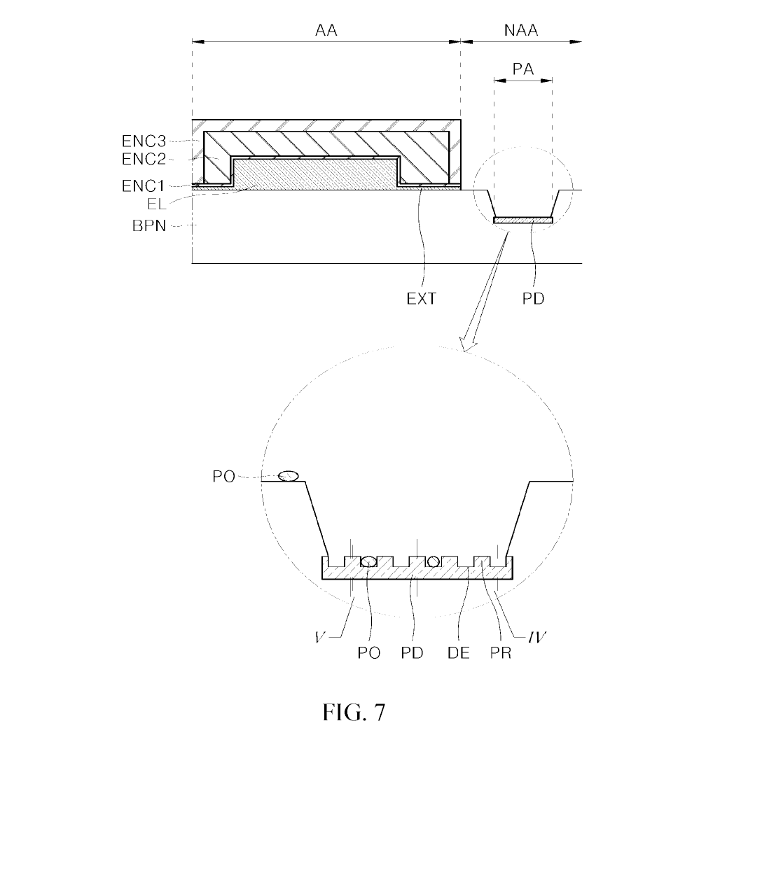

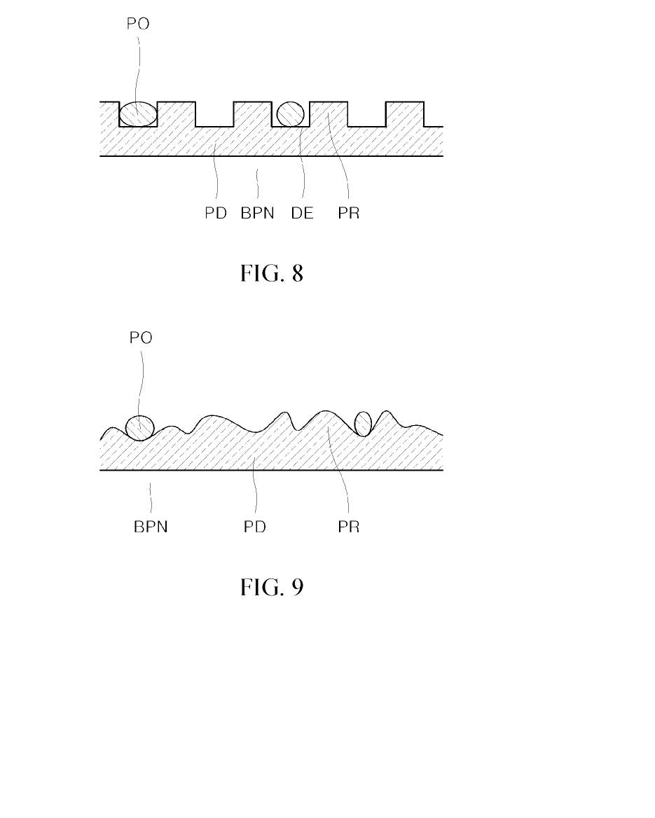

FIGS. 6 and 7 are a cross-sectional view and a partially enlarged view of the display apparatus according to one implementation of the present disclosure before and after a pad open process is performed in a pad area, respectively. FIGS. 8 and 9 are enlarged cross-sectional views of area IV in FIG. 7 in a display panel according to one implementation.

Referring to FIG. 6, at least some layers constituting the light-emitting element layer EL disposed on the active area AA may be formed to cover the entire front surface of the backplane substrate BPN. For example, the light-emitting element layer EL positioned in the active area AA may include an extension EXT in which some layers extend to the non-active area NAA in which the pad area PA is positioned. For example, the extension EXT may include one or more of a hole transport layer, an emissive material layer, and an electron transport layer.

When the extension EXT is formed of multiple layers, the extension EXT is preferably formed to be smaller than the thickness of the light-emitting element layer EL by including only some layers rather than all the layers constituting the light-emitting element layer EL. In a subsequent process of removing the extension EXT formed on the non-active area NAA, it can be easier to remove the extension EXT having a small thickness in terms of the process.

In one implementation, the extension EXT may be formed to continuously extend from the light-emitting element layer EL positioned on the active area AA to cover the entire front surface of the backplane substrate BPN and cover the non-active area NAA and the pad area PA positioned outside the active area AA. The extension EXT positioned on the non-active area NAA including the pad area PA may be defined as the dummy light-emitting element layer DEL. In order for light to be substantially emitted from the light-emitting element layer EL, an overlapping area between the anode electrode AN and the cathode electrode CT needs to be present. However, the dummy light-emitting element layer DEL is formed of the same material as the light-emitting element layer EL, but since no overlapping area between the anode electrode AN and the cathode electrode CT is present so that the dummy light-emitting element layer DEL may not emit light, the dummy light-emitting element layer DEL may be a dummy area that does not serve as a light-emitting element layer.

In another implementation, the extension EXT may be formed discontinuously with the light-emitting element layer EL positioned on the active area AA. For example, the extension EXT may be formed discontinuously with the light-emitting element layer EL within the active area AA. In addition, the extension EXT may be formed continuously with the light-emitting element layer EL within the active area AA, but may be formed discontinuously near the boundary between the active area AA and the non-active area NAA without passing through the encapsulation layer ENC. In this case, an end portion of the extension EXT positioned within the active area AA may be positioned inside an end portion of the encapsulation layer ENC.

The light-emitting element layer EL positioned within the active area AA and the extension EXT positioned within the non-active area NAA including the pad area PA may be positioned discontinuously. The extension EXT positioned discontinuously with the light-emitting element layer EL within the non-active area NAA may be defined as the dummy light-emitting element layer DEL, and the light-emitting element layer EL and the dummy light-emitting element layer DEL may be formed by the same process. In this case, the light-emitting element layer EL may be formed to cover the active area AA, and the dummy light-emitting element layer DEL may be formed to cover the pad area PA of the non-active area NAA. For example, the light-emitting element layer EL and the dummy light-emitting element layer DEL may be formed by a patterning deposition process that may be deposited in a predetermined pattern.

Meanwhile, at least one layer of the encapsulation layer ENC may be formed to cover the entire front surface of the backplane substrate SUB. For example, the first encapsulation layer ENC1 of the encapsulation layer ENC having a multilayered structure may be formed to cover the non-active area NAA in addition to the active area AA. Accordingly, the first encapsulation layer ENC1 may extend to cover the active area AA and the pad area PA located in the non-active area NAA. The first encapsulation layer ENC1 may serve as a protective film to prevent damage to the pad electrode PD during a formation process of various layers. Accordingly, the dummy light-emitting element layer DEL and the first encapsulation layer ENC1 may be sequentially stacked on the pad electrode PD positioned on the pad area PA.

Meanwhile, a plurality of protrusions PR may be formed on the surface of the pad electrode PD. A recess DE may be formed between the plurality of adjacent protrusions PR. Accordingly, a plurality of curved surfaces may be formed on the surface of the pad electrode PD. For example, a predetermined pattern having the protrusion PR and the recess DE may be formed on the surface of the pad electrode PD using a dry etching process, a wet etching process, an electrochemical etching process, a laser etching process, a photolithography process, etc. When the protrusion PR and the recess DE are formed on the surface of the pad electrode PD, the pad electrode PD and the protrusion PR may be formed integrally as a single unit.

For example, referring to FIG. 8, the protrusion PR and the recess DE may be formed in a regular pattern. For example, widths and heights of the plurality of protrusions PR may be formed uniformly. In another example, the protrusion PR and the recess DE are alternately disposed on the surface of the pad electrode PD. However, the present specification is not limited thereto, and referring to FIG. 9, the protrusion PR and the recess DE may be formed in an irregular pattern. For example, the widths and heights of the plurality of protrusions PR may be formed randomly. For reference, when the protrusion PR and the recess DE are formed in an irregular pattern, a larger number of finer protrusions PR can be easily formed than when they are formed in a regular pattern.

Accordingly, the dummy light-emitting element layer DEL and the first encapsulation layer ENC1 that are sequentially stacked on the pad electrode PD may be disposed on the protrusions PR of the pad electrode PD. In this case, the protrusion PR of the pad electrode PD may come into contact with the dummy light-emitting element layer DEL and may not come into direct contact with the first encapsulation layer ENC1.

The pad electrode PD may be formed of the same material as the source/drain electrodes SD of the transistor TR. In addition, the pad electrode PD may be formed on the same layer as the source/drain electrodes SD of the transistor TR using the same process. Accordingly, the pad electrode PD may be formed of a single layer or multiple layers formed of one selected from the group including chromium (Cr), aluminum (Al), silver (Ag), copper (Cu), magnesium (Mg), molybdenum (Mo), and titanium (Ti), or an alloy thereof.

As described above, the dummy light-emitting element layer DEL may be formed to include an organic material such as a hole transport layer, an emissive material layer, and an electron transport layer, and the first encapsulation layer ENC1 may be formed to include an inorganic material such as aluminum oxide. Accordingly, the pad electrode PD may be formed of a material different from the materials constituting the dummy light-emitting element layer DEL and the first encapsulation layer ENC1.

Generally, since bonding strength between a metal and an organic material is weaker than that between a metal and an inorganic material, surface adhesion of the dummy light-emitting element layer DEL in contact with the pad electrode PD may be smaller than surface adhesion of the pad electrode PD and the first encapsulation layer ENC1 coming into contact with each other.

In addition, the dummy light-emitting element layer DEL in contact with the upper surface of the pad electrode PD may be formed to come into contact with the protrusion PR of the pad electrode PD. In this case, since the protrusion PR and the recess DE are alternately disposed on the surface of the pad electrode PD to form a curved portion or an embossed pattern, the surface adhesion of the dummy light-emitting element layer DEL formed on the surface of the pad electrode PD may be greatly reduced.

For example, even when the dummy light-emitting element layer DEL is formed to have a curved portion similar to the curved portion formed on the surface of the pad electrode PD, it is difficult for the dummy light-emitting element layer DEL to be formed in the form of a completely identical curved portion so as to be in contact with the entire front surface of the pad electrode PD, and thus a predetermined separation space may be formed between the protrusion PR and the recess DE of the pad electrode PD and the dummy light-emitting element layer DEL.

A pad open process for exposing the pad electrode PD of the pad area PA to the outside may be performed by the following method. For example, the pad open process may be performed on each display panel PNL present on each die 2 on the wafer 1.

After providing the substrate SUB including the active area AA and the non-active area NAA on which the pad area PA is disposed, a circuit part and a plurality of insulating layers may be formed on the substrate SUB of the active area AA. In this case, the process of forming the circuit part may be a process of forming the transistor TR, and the process of forming a plurality of insulating layers may be a process of forming insulating layers by the same process using the same material as one or more of the first insulating layer INS1, the second insulating layer INS2, the third insulating layer INS3, and the fourth insulating layer INS4.

In addition, one or more pad electrodes PD including the plurality of protrusions PR on the surfaces thereof may be formed on the substrate SUB of the pad area PA. The process of forming the protrusion PR may use various etching processes as described above.

Next, the light-emitting element layer EL and the dummy light-emitting element layer DEL may be formed on the substrate SUB of the active area AA and the pad area PA, respectively. As described above, the dummy light-emitting element layer DEL may be formed by the same process using the same material as the light-emitting element layer EL. In addition, the encapsulation layer may be formed to cover the light-emitting element layer EL and the dummy light-emitting element layer DEL. In this case, the encapsulation layer may be formed by the same process using the same material as the first encapsulation layer ENC1. The process of forming each layer as described above may be shown in FIG. 6.

Next, referring to FIG. 7, the dummy light-emitting element layer DEL and the first encapsulation layer ENC1 on the pad electrode PD may be removed. Since the dummy light-emitting element layer DEL and the first encapsulation layer ENC1 are sequentially stacked on the pad electrode PD, the dummy light-emitting element layer DEL and the first encapsulation layer ENC1 may be removed at once to expose the upper surface of the pad electrode PD. According to the implementation of the present specification, the dummy light-emitting element layer DEL and the first encapsulation layer ENC1 may be removed using a tape peeling process.

As described above, according to the implementation of the present specification, since the plurality of protrusions PR are formed on the surface of the pad electrode PD, the surface adhesion of the organic layer that may be deposited on the surface of the pad electrode PD can be reduced. Accordingly, during the pad open process for removing the protective film formed to cover the pad electrode PD, the organic layer with reduced surface adhesion and the protective film can be removed at once after forming the organic layer on the surface of the pad electrode PD and depositing the protective film thereon, and thus the pad open process can be easily performed to expose the surface of the pad electrode PD to the outside.

In addition, according to the implementations of the present specification, since the protrusion PR formed on the surface of the pad electrode PD is formed by stacking one or more insulating layers including an inorganic material having a very weak bonding strength with the organic material layer, the surface adhesion of the organic material layer that can be deposited on the surface of the pad electrode can be further reduced.

In addition, according to the implementations of the present specification, since the tape peeling process is used during the pad open process, the process can be simplified compared to when using other processes such as a laser process, thereby significantly reducing the manufacturing time and cost.

In addition, according to the implementations of the present specification, since the tape peeling process is used in the pad open process, the occurrence rate of defects in the display apparatus caused by foreign substances such as fine particles that can occur when using other processes such as a laser process can be reduced. Accordingly, it is possible to improve the quality and reliability of the display apparatus.

In addition, according to the implementations of the present specification, since the tape peeling process is used in the pad open process, the pad open process can be performed without setting separate process conditions or without the mask process according to various types of protective films to be removed. Accordingly, it is possible to significantly improve the flexibility of the process and optimize the process, thereby reducing production energy.

Referring to FIG. 7, when the dummy light-emitting element layer DEL is removed, the dummy light-emitting element layer DEL positioned on the non-active area NAA including the pad area PA can be completely removed, and thus, after the dummy light-emitting element layer DEL is removed, the end portion of the encapsulation layer ENC of the active area AA may coincide with the end portion of the extension EXT. As described above, after the dummy light-emitting element layer DEL of the pad area PA is removed, the residual organic material PO may remain locally in some areas on the pad electrode PD. This may occur when a physical removal process such as a tape peeling process is used when removing the dummy light-emitting element layer DEL, and the effect on the residual organic material PO remaining in some areas of the pad electrode PD has been described above.

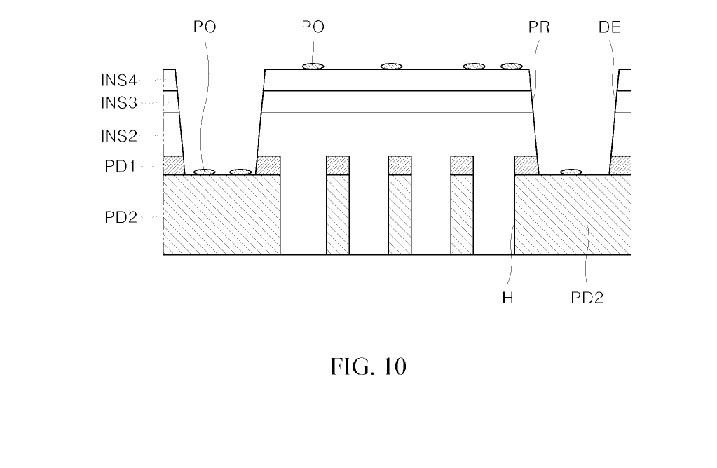

FIG. 10 is an enlarged cross-sectional view of area V in FIG. 7 in a display panel according to another implementation. Referring to FIG. 10, the pad electrode PD and the protrusion PR may be formed of different materials.

The pad electrode PD may be stacked in multiple layers. For example, the pad electrode PD may include a second pad electrode PD2 and a first pad electrode PD1 disposed on the second pad electrode PD2. The second pad electrode PD2 may be formed using the same process and material as the first reflective electrode RE1, and the first pad electrode PD1 may be formed using the same material and process as the first anode electrode AN1. In another example, the second pad electrode PD2 may be formed using the same process and material as the gate electrode GT, and the first pad electrode PD1 may be formed using the same material and process as the source/drain electrodes SD. Also, the pad electrode PD may be stacked in three or more layers.

One or more holes H may be formed in a portion of the surface of the pad electrode PD, and one or more insulating layers may be formed by being stacked on the holes H. For example, when the plurality of insulating layers are stacked, the second insulating layer INS2, the third insulating layer INS3, and the fourth insulating layer INS4 may be sequentially stacked or inserted or filled into the one or more holes H. The insulating layers stacked in this way may fill the hole H positioned thereunder and form the protrusion PR by protruding upward more than the upper surface of the pad electrode PD. In this way, the protrusion PR formed on the surface of the pad electrode PD may be provided as a plurality of protrusions, and the surface of the pad electrode PD may be exposed to the outside through the recess DE between the adjacent protrusions PR. In this case, the first pad electrode corresponding to the pad electrode PD exposed to the outside may be removed, and the second pad electrode PD2 may be exposed to the outside. One or more residual organic materials PO may be formed on the surface of the pad electrode PD or the protrusion PR, which is formed in this way.

In this way, according to another implementation of the present specification, since the material constituting the dummy light-emitting element layer DEL formed on the pad electrode PD and the protrusion PR before the pad open process differs from those of both the pad electrode PD and the protrusion PR, the surface bonding strength of the dummy light-emitting element layer DEL can be further reduced, and thus the pad open process can be performed more easily to expose the surface of the pad electrode PD to the outside.

Although the implementations of the present specification have been described in more detail with reference to the accompanying drawings, the present specification is not necessarily limited to these implementations, and various modifications may be carried out without departing from the technical spirit of the present specification. Accordingly, the implementations disclosed in the present specification are not intended to limit the technical spirit of the present specification, but is intended to describe the same, and the scope of the technical spirit of the present specification is not limited by these implementations. Accordingly, it should be understood that the above-described implementations are illustrative and not restrictive in all aspects.

What is claimed is:

1. A display apparatus comprising:
a substrate including an active area and a non-active area, the non-active area including a pad area;
a light-emitting element layer disposed on the active area;
an encapsulation layer disposed to cover the light-emitting element layer; and
a pad electrode disposed on the pad area,
wherein a surface of the pad electrode includes a plurality of protrusions, and
a residual organic material is positioned on a portion of the pad area.

2. The display apparatus of claim 1, wherein the pad electrode and the plurality of protrusions are integrally a single unit.

3. The display apparatus of claim 1, wherein the pad electrode and the plurality of protrusions comprise different materials.

4. The display apparatus of claim 3, wherein the plurality of protrusions comprise a stack of one or more insulating layers.

5. The display apparatus of claim 4, wherein the one or more insulating layers include an inorganic material.

6. The display apparatus of claim 4, wherein the one or more insulating layers are inserted into one or more holes formed in a portion of the surface of the pad electrode and protrude upward more than the surface of the pad electrode.

7. The display apparatus of claim 1, wherein a recess is arranged between adjacent protrusions in the plurality of protrusions, and
the residual organic material is positioned on the adjacent protrusions or the recess.

8. The display apparatus of claim 7, wherein the recess and the plurality of protrusions are disposed in a regular pattern, and
the residual organic material is randomly disposed in the pad area.

9. The display apparatus of claim 1, wherein the residual organic material comprises a same material as the light-emitting element layer.

10. The display apparatus of claim 1, wherein the light-emitting element layer includes a hole transport layer, an emissive material layer, and an electron transport layer, and
the residual organic material includes a same material as one of the hole transport layer, the emissive material layer, or the electron transport layer.

11. The display apparatus of claim 10, wherein the light-emitting element layer includes an extension extending in a direction in which the pad area is positioned, and
the extension includes one or more of the hole transport layer, the emissive material layer, or the electron transport layer.

12. The display apparatus of claim 11, wherein a vertical thickness of the extension is smaller than a vertical thickness of the light-emitting element layer.

13. The display apparatus of claim 11, wherein an end portion of the encapsulation layer aligns with an end portion of the extension.

14. A method of manufacturing a display apparatus, comprising:
providing a substrate including an active area and a non-active area, the non-active area including a pad area;
forming a circuit part and a plurality of insulating layers on the substrate of the active area;
forming one or more pad electrodes including a plurality of protrusions on a surface of the substrate of the pad area;
forming a light-emitting element layer and a dummy light-emitting element layer on the substrate of the active area and the pad area, respectively;
forming an encapsulation layer to cover the light-emitting element layer and the dummy light-emitting element layer; and
removing the dummy light-emitting element layer and the encapsulation layer on the pad electrode.

15. The method of claim 14, further comprising removing the dummy light-emitting element layer and the encapsulation layer using a tape peeling process.

16. The method of claim 15, wherein, after removing the dummy light-emitting element layer and the encapsulation layer, a residual organic material remains on the pad electrode.

17. The method of claim 14, wherein the light-emitting element layer is formed to include a hole transport layer, an emissive material layer, and an electron transport layer, and
the dummy light-emitting element layer and the residual organic material include a same material as one of the hole transport layer, the emissive material layer, or the electron transport layer.

18. The method of claim 14, wherein the protrusion is formed by using a dry-etching process or a wet-etching process on the surface of the pad electrode.

19. The method of claim 14, wherein the plurality of protrusions are formed by stacking the plurality of insulating layers of the active area.

20. The method of claim 19, wherein at least one of the plurality of insulating layers is formed of an inorganic material.
